(19) United States
(12) Patent Application Publication
(10) Pub. No.: US 2022/0139733 A1
(43) Pub. Date: May 5, 2022

(54) SUBSTRATE PROCESSING APPARATUS AND SUBSTRATE PROCESSING METHOD

(71) Applicant: SCREEN Holdings Co., Ltd., Kyoto (JP)

(72) Inventor: Tomohiro TAKAHASHI, Kyoto-shi (JP)

(21) Appl. No.: 17/513,991

(22) Filed: Oct. 29, 2021

(30) Foreign Application Priority Data
Oct. 30, 2020 (JP) 2020-183212

(51) Int. Cl. H01L 21/67; H01L 21/687

(52) U.S. Cl. CPC H01L 21/67075; H01L 21/68742; H01L 21/67265; H01L 21/67253

(57) ABSTRACT

A substrate processing apparatus includes a substrate holding section that holds a plurality of substrates, which form a substrate row, aligned in a row in a row direction, a processing tank that stores a processing liquid allowing the substrates held by the substrate holding section to be immersed in, and a plurality of bubble generating pipes that each supply a gas to the processing liquid to generate bubbles in the processing liquid. Of the plurality of bubble generating pipes, a flow rate of a gas supplied to an end bubble generating pipe located below an end of the substrate row immersed in the processing liquid differs from a flow rate of a gas supplied to a central bubble generating pipe located below a center of the substrate row.

### INCORPORATION BY REFERENCE

The present application claims priority under 35 U.S.C. § 119 to Japanese Patent Application No. 2020-183212, filed on Oct. 30, 2020. The contents of this application are incorporated herein by reference in their entirety.

### BACKGROUND

The present disclosure relates to a substrate processing apparatus and a substrate processing method.

It is known that substrates used for electronic components such as semiconductor devices and liquid crystal display devices are processed by a substrate processing apparatus. A substrate can be processed by being immersed in a processing liquid in a processing tank.

There is an increasing demand for uniform processing of the substrates according to miniaturizing and/or three-dimensionalizing semiconductor devices formed on semiconductor substrates in recent years. For example, a NAND device having a three-dimensional structure has a laminate structure in which a three-dimensional uneven structure is provided. When the processing liquid stays in concave portions of the uneven structure in a pattern of the device, the liquid replacement in the concave portions becomes insufficient. Therefore, in order to sufficiently promote the liquid replacement for the entire substrate including the concave portions, bubbles may be generated from a bubble generator with the bubble generator located below the substrate immersed in the processing tank to promote liquid replacement in the processing tank.

In a substrate processing apparatus, when a substrate is immersed and processed in a processing tank storing a phosphoric acid aqueous solution, bubbles are generated from a bubble generator located below the substrate immersed in the processing tank. The bubble generator is cylindrical in shape and has a large number of outlets (a large number of openings). A gas supply pipe that supplies water vapor to the bubble generator is connected to one end of the bubble generator. The bubble generator blows the water vapor into the phosphoric acid aqueous solution from each outlet, thereby generating bubbles containing water vapor in the phosphoric acid aqueous solution.

In a substrate processing apparatus, the generation state of bubbles in a liquid is imaged in a substrate processing process, and the amount of bubbles generated from a bubble generator is adjusted based on the imaging result.

### SUMMARY

According to an aspect of the present disclosure, a substrate processing apparatus includes: a substrate holding section that holds a plurality of substrates, which form a substrate row, aligned in a row in a row direction; a processing tank that stores a processing liquid allowing the substrates held by the substrate holding section to be immersed in; and a plurality of bubble generating pipes that each supply a gas to the processing liquid to generate bubbles in the processing liquid. A flow rate of a gas supplied to an end bubble generating pipe, located below an end of the substrate row immersed in the processing liquid, of the plurality of bubble generating pipes differs from a flow rate of a gas supplied to a central bubble generating pipe, located below a center of the substrate row, of the plurality of bubble generating pipes.

In an embodiment, the plurality of bubble generating pipes extend in a direction orthogonal to a normal direction of each main surface of the substrates.

In an embodiment, the central bubble generating pipe is smaller in number per unit area than the end bubble generating pipe.

In an embodiment, the flow rate of the gas supplied to the end bubble generating pipe, located below the end of the substrate row immersed in the processing liquid, of the plurality of bubble generating pipes is larger than the flow rate of the gas supplied to the central bubble generating pipe located below the center of the substrate row.

In an embodiment, the substrate processing apparatus further includes: a plurality of gas supply pipes connected to the plurality of bubble generating pipes; and a flow rate control mechanism that controls a flow rate of a gas flowing through each of the plurality of gas supply pipes. The flow rate control mechanism controls the flow rate of the gas flowing through each of the plurality of gas supply pipes so that the flow rate of the gas supplied to the end bubble generating pipe is larger than the flow rate of the gas supplied to the central bubble generating pipe.

In an embodiment, the substrate processing apparatus further includes a pressure gauge that measures a pressure of a gas flowing through a gas supply pipe connected to the end bubble generating pipe, and a pressure of a gas flowing through a gas supply pipe connected to the central bubble generating pipe.

In an embodiment, the substrate processing apparatus further includes a controller that controls the flow rate control mechanism. The controller controls the flow rate of the gas flowing through each of the plurality of gas supply pipes based on the pressure of the gas flowing through the gas supply pipe connected to the end bubble generating pipe, and the pressure of the gas flowing through the gas supply pipe connected to the central bubble generating pipe.

In an embodiment, the substrate processing apparatus further includes a controller that controls the flow rate control mechanism, and storage that stores a control program. The controller controls the flow rate control mechanism according to the control program.

In an embodiment, the central bubble generating pipe includes a first central pipe and a second central pipe. The first central pipe is located below a first side in a horizontal direction with respect to the substrates. The second central pipe is separated from the first central pipe. The second central pipe is aligned in a straight line along with the first central pipe. The second central pipe is located below a second side in the horizontal direction with respect to the substrates. The end bubble generating pipe includes a first end pipe and a second end pipe. The first end pipe is located below the first side in the horizontal direction with respect to the substrates. The second end pipe is separated from the first end pipe. The second end pipe is aligned in a straight line along with the first end pipe. The second end pipe is located below the second side in the horizontal direction with respect to the substrates.

In an embodiment, the substrate processing apparatus further includes a liquid discharge pipe located in the processing tank.

In an embodiment, the liquid discharge pipe is located so as to extend parallel to the normal direction of each main surface of the substrates.

In an embodiment, the processing liquid contains a phosphoric acid liquid.

According to another aspect of the present disclosure, a substrate processing method includes immersing a plurality of substrates in a processing liquid stored in a processing tank, the plurality of substrates being aligned in a row in a row direction and forming a substrate row; and supplying a gas to each of a plurality of bubble generating pipes arranged in the processing tank to generate bubbles in the processing liquid so that the substrates immersed in the processing liquid are each supplied with the bubbles. The supplying the gas includes making a difference between a flow rate of a gas supplied to an end bubble generating pipe, located below an end of the substrate row, of the plurality of bubble generating pipes and a flow rate of a gas supplied to a central bubble generating pipe, located below a center of the substrate row, of the plurality of bubble generating pipes.

In an embodiment, the plurality of bubble generating pipes extend in a direction orthogonal to a normal direction of each main surface of the substrates.

In an embodiment, in the making the difference, the flow rate of the gas supplied to the end bubble generating pipe, located below the end of the substrate row, of the plurality of bubble generating pipes is larger than the flow rate of the gas supplied to the central bubble generating pipe located below the center of the substrate row.

In an embodiment, the supplying the gas further includes: supplying a gas at an equal flow rate to each of the end bubble generating pipe and the central bubble generating pipe; and measuring, in the supplying the gas at the equal flow rate, a pressure of a gas flowing through a gas supply pipe connected to the end bubble generating pipe, and a pressure of a gas flowing through a gas supply pipe connected to the central bubble generating pipe. The making the difference includes setting, based on a result of the measuring, a flow rate of the gas flowing through the gas supply pipe connected to the end bubble generating pipe, and a flow rate of the gas flowing through the gas supply pipe connected to the central bubble generating pipe.

### BRIEF DESCRIPTION OF THE DRAWINGS

FIGS. 1A and 1B are schematic perspective views of a substrate processing apparatus according to an embodiment.

FIG. 2 is a schematic view of a substrate processing apparatus according to the embodiment.

FIG. 3A is a schematic side view of a substrate processing apparatus according to the embodiment, and FIG. 3B is a schematic top view of a substrate processing apparatus according to the embodiment.

FIG. 4A is a schematic diagram illustrating bubbles generated when a plurality of bubble generating pipes are supplied with their respective gases at an equal flow rate, in a substrate processing apparatus according to the embodiment, and FIG. 4B is a schematic view illustrating the flow of a processing liquid in the substrate processing apparatus according to the embodiment.

FIG. 5A is a schematic side view of a substrate processing apparatus according to the embodiment, and FIG. 5B is a schematic view illustrating bubbles generated when a plurality of bubble generating pipes are supplied with their respective gases at different flow rates, in the substrate processing apparatus according to the embodiment.

FIG. 6 is a schematic view of a substrate processing apparatus according to the embodiment.

FIG. 7 is a flow chart by a substrate processing method according to the embodiment.

FIGS. 8A to 8C are schematic views illustrating changes of a substrate etched by a substrate processing method according to the embodiment.

FIG. 9 is a schematic top view and a partially enlarged view of a substrate processing apparatus according to the embodiment.

FIGS. 10A and 10B are schematic top views of a substrate processing apparatus according to the embodiment.

FIG. 11 is a schematic view of a substrate processing apparatus according to the embodiment.

FIG. 12A is a schematic side view of a substrate processing apparatus according to the embodiment, and FIG. 12B is a schematic top view of a substrate processing apparatus according to the embodiment.

FIG. 13 is a schematic view of a substrate processing apparatus according to the embodiment.

FIG. 14 is a schematic view of a substrate processing apparatus according to the embodiment.

### DETAILED DESCRIPTION

Substrate processing apparatuses and substrate processing methods according to an embodiment of the present disclosure will hereinafter be described with reference to the accompanying drawings. In the drawings, the same or corresponding elements are assigned the same reference signs, and descriptions thereof are not repeated. In the present specification, X-axis, Y-axis and Z-axis that are orthogonal to each other may be described to facilitate understanding of the present disclosure. Typically, the X-axis and Y-axis are parallel to a horizontal direction, and the Z-axis is parallel to a vertical direction. Further, in the present specification, x-axis, y-axis and z-axis that are orthogonal to each other may be described to facilitate understanding of the present disclosure. Typically, the x-axis and y-axis extend parallel to a substrate or a main surface of the substrate, and the z-axis extends in the normal direction of the substrate or the main surface of the substrate.

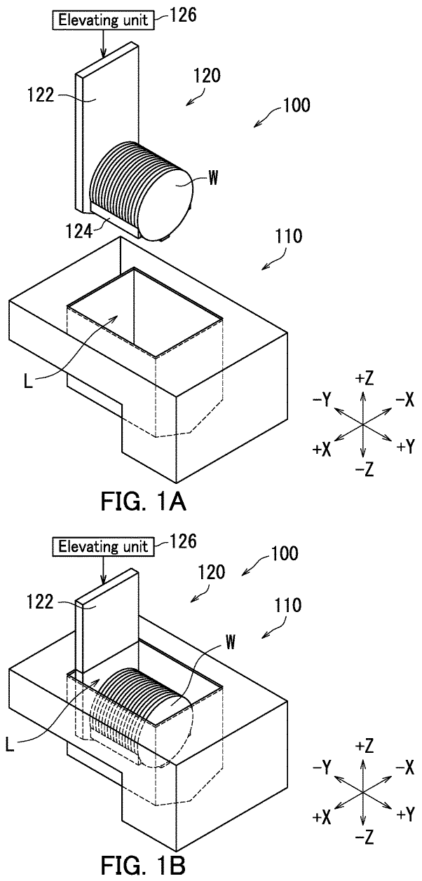

A substrate processing apparatus 100 according to an embodiment of the present disclosure will be described with reference to FIGS. 1A and 1B. FIGS. 1A and 1B are schematic perspective views of the substrate processing apparatus 100 according to the embodiment. FIG. 1A is a schematic perspective view before substrates W are immersed in a processing liquid L in a processing tank 110. FIG. 1B is a schematic perspective view after the substrates W are immersed in the processing liquid L in the processing tank 110.

The substrate processing apparatus 100 processes the substrates W. The substrate processing apparatus 100 may process the substrates W by applying, to the substrates W, at least one of processes that include an etching process, a surface finishing process, a character imparting process, a treatment film forming process, and a film removing and cleaning process for at least partial removal and cleaning of (a) films.

Each substrate W has a thin plate shape. Typically, each substrate W has a substantially thin disk shape. Examples of each substrate W include a semiconductor wafer, a substrate for liquid crystal display, a substrate for plasma display, a substrate for Field Emission Display (FED), a substrate for optical disc, a substrate for magnetic disk, a substrate for magneto-optical disk, a photomask substrate, a ceramic substrate, and a substrate for solar battery.

The substrate processing apparatus 100 processes the substrates W with the processing liquid L. At least one of the processes that include the etching process, the surface finishing process, the character imparting process, the treatment film forming process, and the film removing and cleaning process is applied to the substrates W by using the processing liquid L.

The substrate processing apparatus 100 collectively processes such a plurality of substrates W with the processing liquid L. Note that the substrate processing apparatus 100 may process a large number of substrates W by a predetermined number with the processing liquid L. The predetermined number is an integer of 1 or more. Here, the substrate processing apparatus 100 processes the plurality of substrates W together.

For example, the substrate processing apparatus 100 applies an etching process of a silicone oxide film (SiO₂ film) and a silicon nitride film (SiN film) to a surface, on a pattern formation side, of each substrate W made of a silicon substrate. In such an etching process, either the silicon oxide film or the silicon nitride film is removed from the surface of each substrate W.

The processing liquid L contains phosphoric acid (H₃PO₄). The processing liquid L contains, for example an aqueous phosphoric acid solution, a liquid containing an additive in an aqueous phosphoric acid solution, a mixed acid containing phosphoric acid, or a mixed acid containing phosphoric acid and an additive. For example, the silicon nitride film (SiN film) is removed from the surface of each substrate W with the processing liquid L, namely a solution (hereinafter, referred to as a “phosphoric acid liquid”) at about 157° C. in which approximately 89% by mass of phosphoric acid (H₃PO₄) and approximately 11% by mass of water (deionized water) are mixed. In other words, a high temperature, high acid concentration solution with no impurities is employed as the processing liquid L that dissolves silicon (Si4+). Note that the type of the processing liquid L is not particularly limited as long as the substrates W can be processed. Further, the temperature of the processing liquid L is not particularly limited.

The substrate processing apparatus 100 includes the processing tank 110 and a substrate holding section 120. The processing tank 110 stores the processing liquid L for processing the substrates W.

The substrate holding section 120 holds the substrates W. A normal direction of a main surface of each substrate W held by the substrate holding section 120 is parallel to the Y-axis. The plurality of substrates W are aligned in a row along the Y-axis. In other words, the plurality of substrates W are aligned substantially parallel in the horizontal direction. The normal of the plurality of substrates W extends along the Y-axis, and each of the plurality of substrates W extends along the X-axis. The substrate holding section 120 moves the substrates W while holding the substrates W. For example, the substrate holding section 120 moves vertically upward or downward in the vertical direction while holding the substrates W.

Typically, the substrate holding section 120 holds the plurality of substrates W together. Here, the substrate holding section 120 holds the substrates W, which forms a substrate row, aligned in a row along the Y-axis.

Specifically, the substrate holding section 120 includes a lifter. The substrate holding section 120 moves vertically upward or downward while holding the plurality of substrates W. The substrate holding section 120 moves vertically downward, so that the plurality of substrates W held by the substrate holding section 120 are immersed in the processing liquid L stored in the processing tank 110.

In FIG. 1A, the substrate holding section 120 is located above the processing tank 110. The substrate holding section 120 descends vertically downward (Z-axis) while holding the plurality of substrates W. As a result, the plurality of substrates W are put into the processing tank 110.

As illustrated in FIG. 1B, when the substrate holding section 120 descends into the processing tank 110, the plurality of substrates W are immersed in the processing liquid L in the processing tank 110. The substrate holding section 120 immerses, in the processing liquid L stored in the processing tank 110, the plurality of substrates W aligned at predetermined intervals.

The substrate holding section 120 further includes a body plate 122 and holding rods 124. The body plate 122 is a plate extending in the vertical direction (Z-axis). The holding rods 124 extend in the horizontal direction (Y-axis) from one main surface of the body plate 122. In FIGS. 1A and 1B, three holding rods 124 extend horizontally from the one main surface of the body plate 122. The plurality of holding rods 124 are in contact with the lower edge of each substrate W, whereby the plurality of substrates W aligned at predetermined intervals are held in that state and in an upright posture (vertical posture) by the plurality of holding rods 124.

The substrate holding section 120 may further include an elevating unit 126. The elevating unit 126 moves the body plate 122 up and down between a processing position (position illustrated in FIG. 1B) where the plurality of substrates W held by the substrate holding section 120 are located in the processing tank 110 and a retracted position (position illustrated in FIG. 1A) where the plurality of substrates W held by the substrate holding section 120 are located above the processing tank 110. Therefore, the body plate 122 is moved to the processing position by the elevating unit 126, so that the plurality of substrates W held by the holding rods 124 are immersed in the processing liquid L.

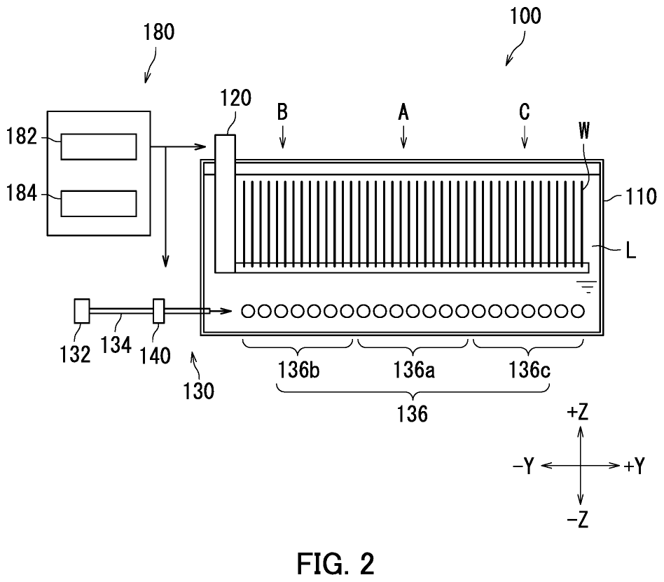

Next, a substrate processing apparatus 100 according to the embodiment will be described with reference to FIGS. 1A, 1B and 2. FIG. 2 is a schematic view of the substrate processing apparatus 100.

As illustrated in FIG. 2, here, the substrate processing apparatus 100 is divided into three regions according to the position in the alignment direction (Y direction) of the substrates W. The three regions include a central region A, an end region B, and an end region C. The end region B, the central region A, and the end region C are located in this order along the Y-axis along which the substrates W are aligned. The central region A is located between the end region B and the end region C. The end region B is located on the negative half side of the Y-axis with respect to the central region A. The end region C is located on the positive half side of the Y-axis with respect to the central region A.

The substrate processing apparatus 100 further includes a gas supply section 130 and a control device 180. The gas supply section 130 supplies a gas to the processing tank 110. Specifically, the gas supply section 130 supplies the gas to a processing liquid L stored in a processing tank 110. The gas supply section 130 supplies the gas to the processing tank 110, so that the processing of the substrates W is promoted.

The gas supply section 130 supplies the gas to the processing tank 110, so that bubbles are formed in the processing liquid L. The bubbles formed in the processing liquid L float in the processing liquid L and reach the interface between gas (for example, air or a predetermined atmosphere) and the processing liquid L in the processing tank 110.

When the bubbles float in the processing liquid L, the bubbles come into contact with respective surfaces of the substrates W. In this case, since the phosphoric acid is agitated by the bubbles, the unevenness of silicon concentration in the phosphoric acid can be eliminated. Therefore, the etching uniformity can be improved.

The gas supply section 130 includes a gas supply source 132, gas supply pipes 134, and bubble generating pipes 136. The gas supply source 132 stores the gas. The gas is supplied from the gas supply source 132.

The gas supply pipes 134 connect the gas supply source 132 and the bubble generating pipes 136. The gas supplied from the gas supply source 132 flows through the gas supply pipes 134 to the bubble generating pipes 136.

The bubble generating pipes 136 are arranged in the processing tank 110.

Typically, the bubble generating pipes 136 are arranged at the bottom side of the processing tank 110.

The plurality of bubble generating pipes 136 are arranged every other between the substrates W aligned in the alignment direction. The plurality of bubble generating pipes 136 are arranged over the central region A, the end region B, and the end region C. In the present specification, of the plurality of bubble generating pipes 136, the bubble generating pipes 136 located below the substrates W in the central region A may be referred to as central bubble generating pipes 136a. Further, in the present specification, of the plurality of bubble generating pipes 136, the bubble generating pipes 136 located below the substrates W in the end region B may be referred to as end bubble generating pipes 136b, and the bubble generating pipes 136 located below the substrates W in the end region C may be referred to as end bubble generating pipes 136c.

For example, the plurality of bubble generating pipes 136 may be classified into the central bubble generating pipes 136a, the end bubble generating pipes 136b, and the end bubble generating pipes 136c in an equal or substantially equal number. Alternatively, the plurality of bubble generating pipes 136 may be unevenly classified into the central bubble generating pipes 136a, the end bubble generating pipes 136b, and the end bubble generating pipes 136c. For example, when the number of bubble generating pipes 136 is 7 or more, each group of the central bubble generating pipes 136a, the end bubble generating pipes 136b, and the end bubble generating pipes 136c preferably includes two or more bubble generating pipes 136. Also, the number of end bubble generating pipes 136b may be equal to the number of end bubble generating pipes 136c. Further, the number of central bubble generating pipes 136a may be smaller than the sum of the number of end bubble generating pipes 136b and the number of end bubble generating pipes 136c. Alternatively, the number of central bubble generating pipes 136a may be smaller than each of the number of end bubble generating pipes 136b and the number of end bubble generating pipes 136c.

The gas supply section 130 may further include flow rate control mechanisms 140. The flow rate control mechanisms 140 are attached to the gas supply pipes 134. The flow rate control mechanisms 140 control a pressure and/or a flow rate of a gas flowing through each gas supply pipe 134. For example, the flow rate control mechanisms 140 control the flow rates of respective gases flowing through the gas supply pipes 134. As an example, the flow rate control mechanisms 140 control the flow rates of respective gases according to the process, with the pressures of respective gases flowing through the gas supply pipes 134 being fixed at a constant level.

For example, each flow rate control mechanism 140 includes a nozzle or a regulating valve that opens and closes a flow path of a corresponding gas supply pipe 134. Note that the flow control mechanism 140 may include a pressure gauge and a flow meter.

As described above, the bubble generating pipes 136 are arranged in the processing tank 110. On the other hand, the gas supply source 132 and the flow rate control mechanisms 140 are located outside the processing tank 110. Further, the gas supply pipes 134 are arranged outside the processing tank 110. Note that at least part of each gas supply pipe 134 may be arranged in the processing tank 110 to be connected to a corresponding bubble generating pipe 136 in the processing tank 110.

The control device 180 controls various operations of the substrate processing apparatus 100. Typically, the control device 180 controls the gas supply section 130. For example, the control device 180 controls the flow rate control mechanisms 140.

The control device 180 includes a controller 182 and storage 184. The controller 182 includes a processor. For example, the controller 182 includes a central processing unit (CPU). Alternatively, the controller 182 may have a general-purpose arithmetic unit.

The storage 184 stores data and a computer program(s). The data includes recipe data. The recipe data includes information indicating a plurality of recipes. Each recipe defines processing content and processing procedure of the substrates W.

The storage 184 includes main storage and auxiliary storage. For example, the main storage is a semiconductor memory. The auxiliary storage is, for example a semiconductor memory and/or a hard disk drive. The storage 184 may include removable media. The controller 182 executes the computer program stored in the storage 184 to execute a substrate processing operation.

The storage 184 stores a computer program describing a procedure in advance. The substrate processing apparatus 100 operates according to the procedure described in the computer program.

The controller 182 controls the gas supply section 130. The gas supply from the gas supply section 130 is controlled by the controller 182. Specifically, the controller 182 controls the start and stop of the gas supply by the gas supply section 130. Further, the controller 182 controls the flow rate control mechanisms 140 to control a flow rate of a gas supplied to each of the bubble generating pipes 136 in the processing tank 110. In one example, the controller 182 may control the nozzles, the regulating valves or the like provided in the gas supply pipes 134 outside the processing tank 110, thereby controlling the supply of respective gases to the bubble generating pipes 136.

The controller 182 also controls the elevating unit 126. According to the control by the controller 182, the body plate 122 moves up and down with respect to the processing liquid L in the processing tank 110.

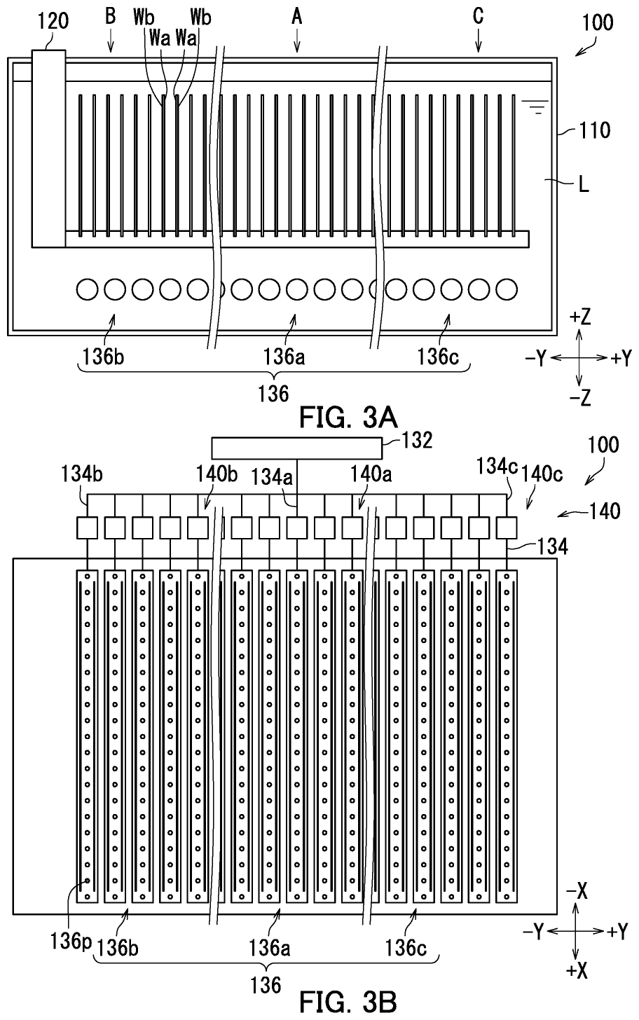

Next, a substrate processing apparatus 100 according to the embodiment will be described with reference to FIGS. 3A and 3B. FIG. 3A is a schematic side view of the substrate processing apparatus 100 according to the embodiment. FIG. 3B is a schematic top view of the substrate processing apparatus 100 according to the embodiment. Here, FIGS. 3A and 3B separately illustrate a central region A, an end region B, and an end region C of a processing tank 110 in the substrate processing apparatus 100. Further, in FIG. 3B, a substrate holding portion 120 is omitted.

As illustrated in FIG. 3A, the substrate holding section 120 holds a plurality of substrates W aligned in a row along the Y-axis. The plurality of substrates W are aligned at equal intervals. For example, the distance between each adjacent substrates W is 2 mm or more and 20 mm or less.

Each substrate W has a main surface Wa and a main surface Wb. The main surface Wa is the front surface of the substrate W, and the main surface Wb is the back surface of the substrate W. Here, the plurality of substrates W are aligned with the main surfaces Wa of adjacent substrates W facing each other and with the main surfaces Wb of adjacent substrates W facing each other.

Here, bubble generating pipes 136 extend in a direction intersecting the alignment direction of the substrates W. Each bubble generating pipe 136 is located between corresponding two adjacent substrates W of the plurality of substrates W. The bubble generating pipes 136 extend along the X-axis. The bubble generating pipes 136 are arranged every other row in the alignment direction of the plurality of substrates W.

The bubble generating pipes 136 are located below the substrates W held by the substrate holding section 120. Typically, the bubble generating pipes 136 are arranged at the bottom side of the processing tank 110.

As illustrated in FIG. 3B, each bubble generating pipe 136 is provided with a plurality of openings 136p. The plurality of openings 136p are aligned in a row in the bubble generating pipe 136. The plurality of openings 136p are aligned at equal intervals. Each opening 136p in each bubble generating pipe 136 is located between corresponding two substrates W aligned in the alignment direction (Y-axis).

The bubble generating pipes 136 include central bubble generating pipes 136a, end bubble generating pipes 136b, and end bubble generating pipes 136c. The end bubble generating pipes 136b, the central bubble generating pipes 136a, and the end bubble generating pipes 136c are arranged in this order from the negative half side to the positive half side of the Y-axis. Each of the bubble generating pipes 136 is provided with the plurality of openings 136p. Here, the plurality of openings 136p are equal in size and intervals. As described above, each bubble generating pipe 136 has a similar structure.

A gas supply source 132 is connected to each of a plurality of gas supply pipes 134. The gas supply pipes 134 connect the gas supply source 132 and the bubble generating pipes 136, respectively. Further, flow rate control mechanisms 140 are individually attached to the gas supply pipes 134. A gas supplied from the gas supply source 132 flows through each gas supply pipe 134 to a corresponding bubble generating pipe 136. Therefore, the bubble generating pipes 136 are supplied, from the gas supply source 132 through the gas supply pipes 134, with their respective gases whose flow rates are controlled by the flow rate control mechanisms 140.

The flow rates of gases (gas flow rates) supplied to the bubble generating pipes 136 can be controlled by the flow rate control mechanisms 140. The flow rate control mechanisms 140 enable the central bubble generating pipes 136a, the end bubble generating pipes 136b, and the end bubble generating pipes 136c to be supplied with their respective gases at an equal flow rate. Alternatively, the flow rate control mechanisms 140 enable the central bubble generating pipes 136a, the end bubble generating pipes 136b, and the end bubble generating pipes 136c to be supplied with their respective gases at different flow rates.

In the present specification, of the plurality of gas supply pipes 134, the gas supply pipes 134 connected to the central bubble generating pipes 136a may be referred to as gas supply pipes 134a. Similarly, of the plurality of gas supply pipes 134, the gas supply pipes 134 connected to the end bubble generating pipes 136b may be referred to as gas supply pipes 134b, and the gas supply pipes 134 connected to the end bubble generating pipes 136c may be referred to as gas supply pipes 134c.

Further, in the present specification, of a plurality of flow rate control mechanisms 140, the flow rate control mechanisms 140 that control the flow rates of gases supplied to the gas supply pipes 134a may be referred to as flow rate control mechanisms 140a. Similarly, the flow rate control mechanisms 140 that control the flow rates of the gases supplied to the gas supply pipes 134b may be referred to as flow rate control mechanisms 140b, and the flow rate control mechanisms 140 that control the flow rate of gases supplied to the gas supply pipes 134c may be referred to as flow rate control mechanisms 140c.

Here, the plurality of bubble generating pipes 136 are supplied with their respective gases from the same gas supply source 132. However, the plurality of bubble generating pipes 136 may be supplied with their respective gases from different gas supply sources 132. In this case, the bubble generating pipes 136 may be supplied, from the gas supply sources 132, with their respective gases at a predetermined flow rate.

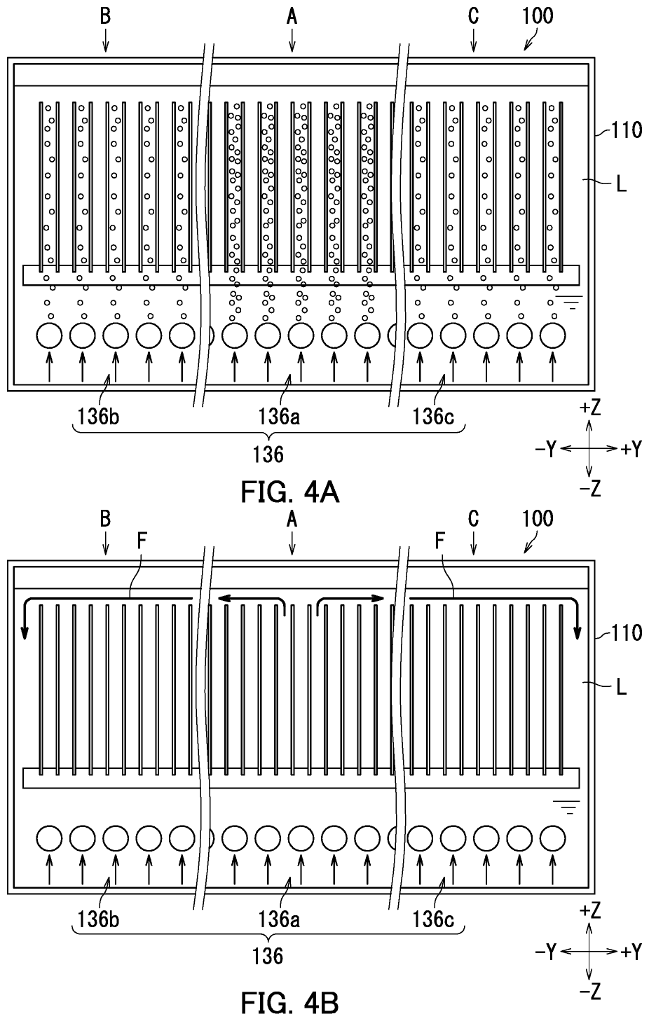

Next, a substrate processing apparatus 100 according to the embodiment will be described with reference to FIGS. 1A to 4B. FIGS. 4A and 4B are schematic views of the substrate processing apparatus 100. FIG. 4A illustrates bubbles generated when a plurality of bubble generating pipes 136 are supplied with their respective gases at an equal flow rate, in the substrate processing apparatus 100. FIG. 4B illustrates the flows of a processing liquid L during bubble generation, in the substrate processing apparatus 100 according to the embodiment. Here, the bubble generating pipes 136 are supplied with their respective gases at an equal flow rate through flow rate control mechanisms 140a to 140c.

As illustrated in FIG. 4A, the bubble generating pipes 136 are supplied with their respective gases, and then each generate bubbles in the processing liquid L. The bubble generating pipes 136 each discharge the gas into the processing liquid L in a processing tank 100, so that bubbles are generated in the processing liquid L. The bubbles generated in the processing liquid L float in the processing liquid L and reach the interface between gas (for example, air or a predetermined atmosphere) and the processing liquid L in the processing tank 110.

While the bubbles float in the processing liquid L, the bubbles come into contact with respective surfaces of the substrates W. In this case, since the phosphoric acid is agitated by the bubbles, the unevenness of the silicon concentration in the phosphoric acid is eliminated, so that the etching uniformity can be improved.

For example, the amount of bubbles generated from each end bubble generating pipe 136b is smaller than the amount of bubbles generated from each central bubble generating pipe 136a. Similarly, the amount of bubbles generated from each end bubble generating pipe 136c is smaller than the amount of bubbles generated from each central bubble generating pipe 136a.

FIG. 4B illustrates flows F of the processing liquid L by the bubbles generated through the bubble generating pipes 136. When the bubbles float up, the processing liquid L flows to the interface between the gas (for example, air or a predetermined atmosphere) and the processing liquid L in the processing tank 110, and then flows toward positive and negative half sides of the Y-axis at the upper part of the processing liquid L. The processing liquid L subsequently forms downward flows directed downward along the side walls of the processing tank 110 on the positive and negative half sides of the X-axis.

Therefore, the end bubble generating pipes 136b and the end bubble generating pipes 136c at both ends of the processing tank 110 are strongly affected by the downward flows of the processing liquid L from up to down in the processing tank 110, compared with the central bubble generating pipes 136a at a center of the processing tank 110. Therefore, even if the bubble generating pipes 136 are supplied with their respective gases at an equal flow rate, the etching amount by the bubbles generated from the bubble generating pipes 136 may not be uniform. Specifically, the amount of bubbles generated from each of the end bubble generating pipes 136b and the end bubble generating pipes 136c is smaller than the amount of bubbles generated from each of the central bubble generating pipes 136a.

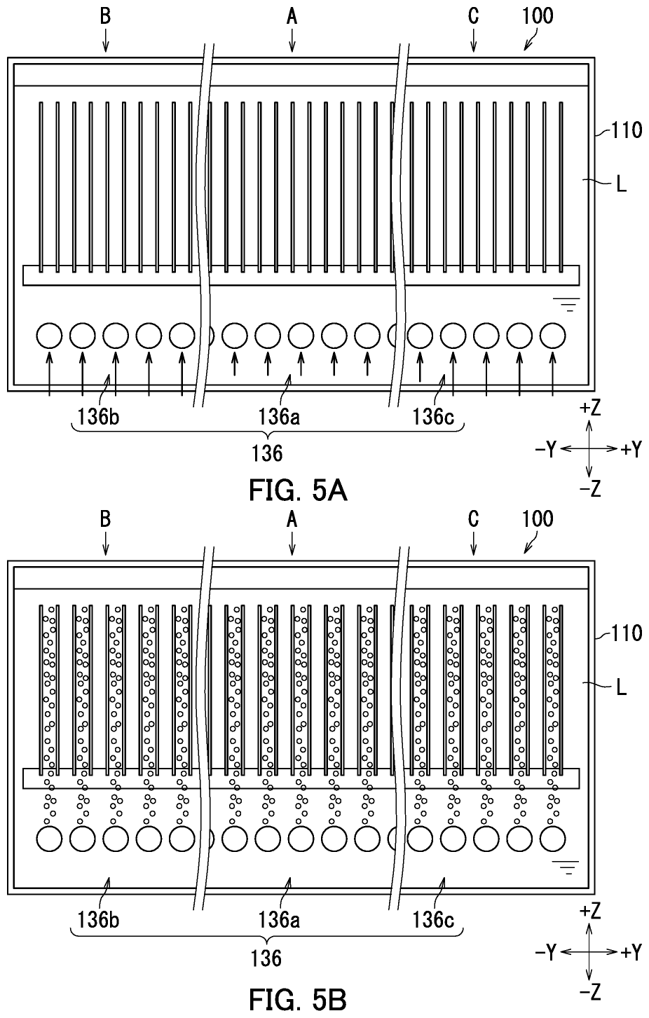

Next, a substrate processing apparatus 100 according to the embodiment will be described with reference to FIGS. 1A to 5B. FIG. 5A is a schematic top view of the substrate processing apparatus 100 according to the embodiment. FIG. 5B is a schematic view of the substrate processing apparatus 100 according to the embodiment in which a plurality of bubble generating pipes 136 are supplied with their respective gases at different flow rates, thereby generating bubbles.

As illustrated in FIG. 5A, the bubble generating pipes 136 are supplied with their respective gases at different flow rates according to control by flow rate control mechanisms 140. Specifically, the flow rate control mechanisms 140a and 140b control the flow rates of gases flowing through gas supply pipes 134a and 134b so that the flow rate of a gas supplied to each end bubble generating pipe 136b is larger than the flow rate of a gas supplied to each central bubble generating pipe 136a. Further, the flow rate control mechanisms 140a and 140b control the flow rates of gases flowing through gas supply pipes 134a and 134c so that the flow rate of a gas supplied to each end bubble generating pipe 136c is larger than the flow rate of a gas supplied to each central bubble generating pipe 136a. Therefore, the flow rate of the gas supplied to each of the end bubble generating pipes 136b and 136c is larger than the flow rate of the gas supplied to each central bubble generating pipes 136a.

As illustrated in FIG. 5B, the bubble generating pipes 136 are supplied with their respective gases, and then each generate bubbles into a processing liquid L. Here, the central bubble generating pipes 136a, and the end bubble generating pipes 136b and 136c each generate bubbles in almost an equal amount. Specifically, the central bubble generating pipes 136a, and the end bubble generating pipes 136b and 136c each generate bubbles having substantially the same size at the same frequency. This enables the central bubble generating pipes 136a, and the end bubble generating pipes 136b and 136c to be supplied with their respective gases at different flow rates so that the central bubble generating pipes 136a, and the end bubble generating pipes 136b and 136c each generate bubbles at almost an equal amount.

The upper limit of the flow rates of the gases supplied to the bubble generating pipes 136 is set so that the processing liquid L in the processing tank 110 does not overflow from the processing tank. For example, the upper limit of the flow rates of the gases supplied to the bubble generating pipes 136 is set based on the internal volume of the processing tank 110, the amount of the processing liquid L, the temperature of the processing liquid L, and the like. Further, the lower limit of the flow rates of the gases supplied to the bubble generating pipes 136 is set according to the presence or absence of bubbles generated from the bubble generating pipes 136.

In the substrate processing apparatus 100 according to the embodiment, the flow rates of the gases supplied to the end bubble generating pipes 136b and 136c are made larger than the flow rates of the gases supplied to the central bubble generating pipes 136a. This enables the central bubble generating pipes 136a and the end bubble generating pipes 136b and 136c to each generate bubbles at almost an equal amount, thereby suppressing processing unevenness for each substrate W.

In FIGS. 2 to 5B, the bubble generating pipes 136 are arranged at equal intervals, but the embodiment is not limited to this. Intervals at which the central bubble generating pipes 136a are arranged may be relatively long, while intervals at which the end bubble generating pipes 136b and 136c are arranged may be relatively short. In this case, the number of central bubble generating pipes 136a per unit area may be smaller than the number of end bubble generating pipes 136b and 136c per unit area.

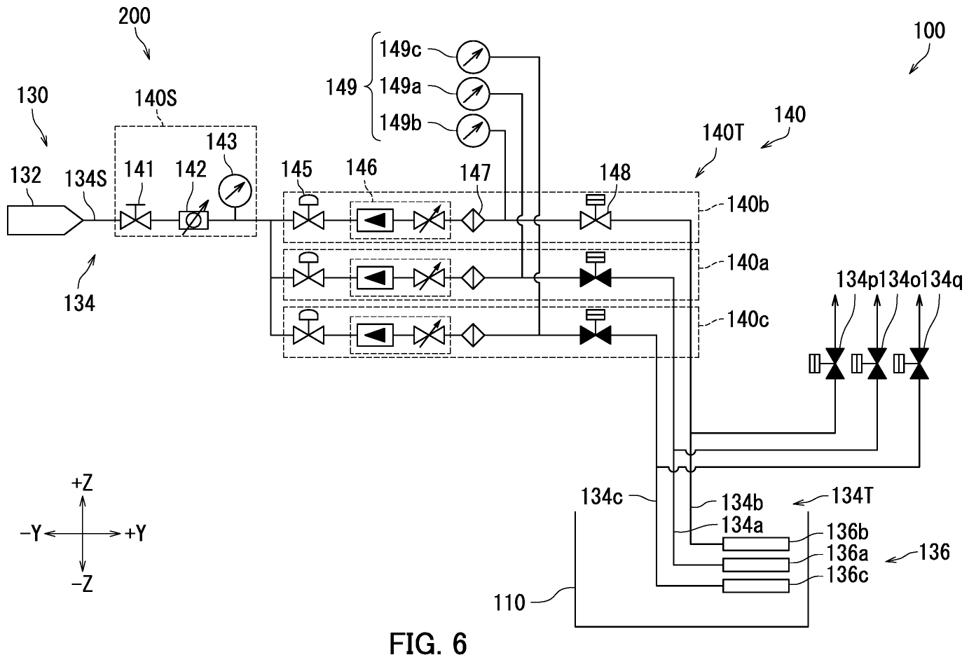

Next, a substrate processing apparatus 100 according to the embodiment will be described with reference to FIG. 6. FIG. 6 is a schematic view of the substrate processing apparatus 100 according to the embodiment.

As illustrated in FIG. 6, a gas supply section 130 includes a gas supply source 132, gas supply pipes 134, bubble generating pipes 136, and flow rate control mechanisms 140. Here, the bubble generating pipes 136 arranged in a processing tank 110 are supplied with their respective gases to each generate bubbles in a processing liquid L, so that a plurality of substrates W immersed in the processing liquid L are each supplied with bubbles.

The bubble generating pipes 136 include central bubble generating pipes 136a, end bubble generating pipes 136b, and end bubble generating pipes 136c. Note that the central bubble generating pipes 136a, the end bubble generating pipes 136b, end bubble generating pipes 136c, the gas supply pipes 134a to 134c, and the flow rate control mechanisms 140a to 140c are provided two or more each, but illustrated one each as a representative in FIG. 6.

The gas supply pipes 134 include a common pipe 134S and individual pipes 134T. The individual pipes 134T include the gas supply pipes 134a, the gas supply pipes 134b, and the gas supply pipes 134c.

The common pipe 134S connects the gas supply source 132 and individual pipes 134T. Specifically, the upstream end of the common pipe 134S is connected to the gas supply source 132. The gas supply source 132 supplies a gas to the common pipe 134S. The downstream end of the common pipe 134S is connected to respective upstream ends of the gas supply pipes 134a to 134c.

Respective downstream ends of the gas supply pipes 134a are connected to the central bubble generating pipes 136a. Respective downstream ends of the gas supply pipes 134b are connected to the end bubble generating pipes 136b. Respective downstream ends of the gas supply pipes 134c are connected to the end bubble generating pipes 136c. Therefore, the central bubble generating pipes 136a, and the end bubble generating pipes 136b and 136c are supplied with their respective gases from the gas supply source 132 through the common pipe 134S and the gas supply pipes 134a to 134c.

The flow rate control mechanisms 140 include a common control mechanism 140S and individual control mechanisms 140T. The individual control mechanisms 140T include the flow rate control mechanisms 140a, the flow rate control mechanisms 140b, and the flow rate control mechanisms 140c.

The common control mechanism 140S includes a valve 141, a regulator 142, and a pressure gauge 143. The valve 141, the regulator 142, and the pressure gauge 143 are arranged in this order in the common pipe 134S from the upstream side to the downstream side of the common pipe 134S. When the valve 141 is opened, a gas flows from the gas supply source 132 through the common pipe 134S. The regulator 142 adjusts the pressure of the gas passing through the common pipe 134S to a predetermined value. The pressure gauge 143 detects the pressure in the common pipe 134S. The pressure gauge 143 is connected between the regulator 142 and the individual pipes 134T.

The flow rate control mechanisms 140b each control the flow rate of a gas supplied from the gas supply source 132. The end bubble generating pipes 136b are supplied, through the gas supply pipes 134b, with their respective gases whose flow rates are controlled. For example, each flow rate control mechanism 140b includes an adjustment valve 145, a flow meter 146, a filter 147, and a valve 148. The adjustment valve 145, the flow meter 146, the filter 147 and the valve 148 are arranged in this order in the gas supply pipe 134b from the upstream side to the downstream side of the gas supply pipe 134b.

The adjustment valve 145 adjusts the opening degree to adjust a flow rate of a gas supplied to the end bubble generating pipe 136b. The “flow rate” indicates, for example the amount of the gas passing therethrough a unit area per unit time. Specifically, the adjustment valve 145 includes a valve body (not illustrated) having a valve seat inside, a valve element that opens and closes the valve seat, and an actuator (not illustrated) that moves the valve element between an open position and a closed position.

The adjustment valve 145 adjusts the flow rate of the gas based on the measurement result by the flow meter 146. Note that the adjustment valve 145 may be an adjustment valve of a mass flow controller (MFC), for example.

The flow meter 146 measures the flow rate of the gas flowing through the gas supply pipe 134b. The filter 147 filters the gas flowing through the gas supply pipe 134b.

The valve 148 opens and closes the gas supply pipe 134b. Therefore, the valve 148 switches between the start and stop of the supply of the gas from the gas supply pipe 134b to the bubble generating pipe 136b.

Similarly, each flow rate control mechanism 140a controls a flow rate of a gas supplied from the gas supply source 132. Further, each flow rate control mechanism 140c controls a flow rate of a gas supplied from the gas supply source 132.

The substrate processing apparatus 100 illustrated in FIG. 6 further includes a plurality of pressure gauges 149. The plurality of pressure gauges 149 include pressure gauges 149a, pressure gauges 149b, and pressure gauges 149c.

The pressure gauges 149a detect pressures of the gases in the gas supply pipes 134a. The pressure gauges 149b detect pressures of the gases in the gas supply pipes 134b. The pressure gauges 149c detect pressures of the gases in the gas supply pipes 134c.

The substrate processing apparatus 100 further includes a plurality of exhaust mechanisms 134o, 134p, and 134q. The exhaust mechanisms 134o are connected to the gas supply pipes 134a. The exhaust mechanisms 134p are connected to the gas supply pipes 134b. The exhaust mechanisms 134q are connected to the gas supply pipes 134c.

Each of the exhaust mechanisms 134o to 134q discharges the gas to the outside. Specifically, each of the exhaust mechanisms 134o to 134q includes an exhaust pipe and a valve. The valve is placed in the exhaust pipe. The valve opens and closes the exhaust pipe. One end of the exhaust pipe is connected to a corresponding gas supply pipe 134. When the valve opens, the gas is discharged outside from the gas supply pipe 134 through the exhaust pipe.

In this way, the flow rate of the gas flowing through each of the gas supply pipes 134a to 134c can be appropriately controlled. Therefore, the amount of bubbles generated from each of the bubble generating pipes 136a to 136c can be appropriately controlled.

As described above, the amount of bubbles generated from each of the bubble generating pipes 136a to 136c varies according to the flow rate of the gas flowing through each of the gas supply pipes 134a to 134c. When the flow rate control mechanisms 140a to 140c control the flow rates of the gases flowing through the gas supply pipes 134a to 134c, a control device 180 (FIG. 2) may control the flow rate control mechanisms 140a to 140c according to values preset in a control program. Alternatively, the control device 180 may supply the gases to the substrates W to be processed, measure the flow rates or pressures of the gases flowing through the gas supply pipes 134a to 134c, and set the flow rates of the gases to flow through the gas supply pipes 134a to 134c.

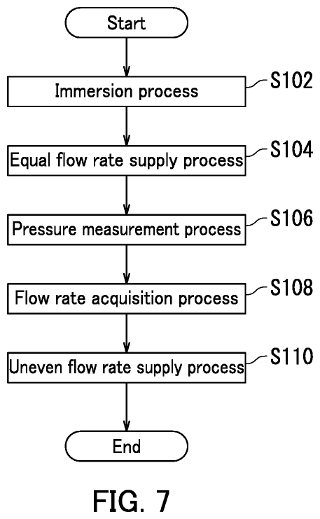

Next, a substrate processing method according to the embodiment will be schematically described with reference to FIGS. 1A to 7. FIG. 7 is a flow chart according to the substrate processing method according to the embodiment.

As illustrated in FIG. 7, in step S102, a substrate holding section 120 descends substrates W in a processing tank 110 while holding the substrates W. As a result, the substrates W are immersed in a processing liquid L in the processing tank 110.

In step S104, flow rate control mechanisms 140a to 140c control flow rates of gases flowing through gas supply pipes 134a to 134c so that central bubble generating pipes 136a, and end bubble generating pipes 136b and 136c are supplied with their respective gases at an equal flow rate (see equal flow rate supply process in FIGS. 4A and 4B).

In step S106, respective pressures of the gases in the gas supply pipes 134a to 134c are measured while the central bubble generating pipes 136a, and the end bubble generating pipes 136b and 136c are supplied with their respective gases at an equal flow rate (pressure measurement process). The pressures of the gases in the gas supply pipes 134a to 134c act as an index indicating the ease of generating bubbles in the processing tank 110. For example, the pressure gauges 149a to 149c illustrated in FIG. 6 measure the pressures of the gases in the gas supply pipes 134a to 134c, respectively.

In step S108, the flow rates of the gases to flow through the gas supply pipes 134a to 134c are acquired according to the pressures of the gases in the gas supply pipes 134a to 134c (flow rate acquisition process). Typically, the control device 180 acquires the flow rates of the gases to flow through the gas supply pipes 134a to 134c based on the measurement results by the pressure gauges 149a to 149c.

In step S110, based on the acquired flow rates, the flow rate control mechanisms 140a to 140c control the flow rates of the gases flowing through the gas supply pipes 134a to 134c so that the central bubble generating pipes 136a, and the end bubble generating pipes 136b and 136c are supplied with their respective gases at different flow rates (see uneven flow rate supply process in FIGS. 5A and 5B). In this case, the flow rate control mechanisms 140a and 140b control the flow rates of the gases flowing through the gas supply pipes 134a and 134b so that the flow rates of the gases supplied to the end bubble generating pipes 136b are larger than the flow rates of the gases supplied to the central bubble generating pipes 136a. Further, the flow rate control mechanisms 140a and 140c control the flow rates of the gases flowing through the gas supply pipes 134a and 134c so that the flow rates of the gases supplied to the end bubble generating pipes 136c are larger than the flow rates of the gases supplied to the central bubble generating pipes 136a. The central bubble generating pipes 136a, and the end bubble generating pipes 136b and 136c are supplied with their respective gases at different flow rates, thereby each generating bubbles at almost an equal amount. As described above, even if the conditions of the substrates W, the processing environment, and the processing liquid L are different, the central bubble generating pipes 136a, and the end bubble generating pipes 136b and 136c can each generate bubbles at almost an equal amount, so that the processing unevenness among the substrates W can be suppressed.

Note that the substrate processing apparatus 100 and the substrate processing method according to the embodiment are suitably used for manufacturing NAND devices.

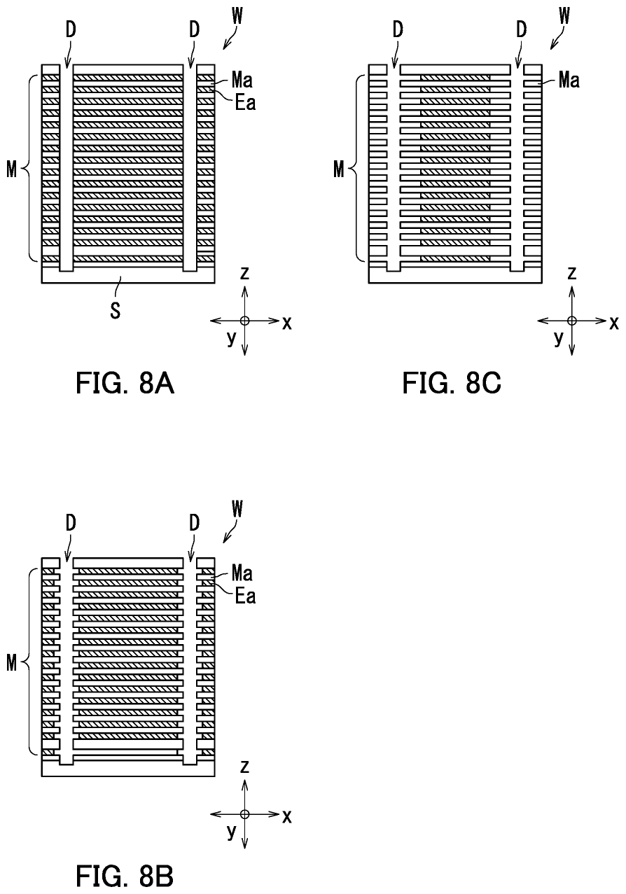

Next, a substrate processing method according to the embodiment will be schematically described with reference to FIGS. 1A to 8C. FIGS. 8A to 8C are schematic views of a substrate W processed by the substrate processing method according to the embodiment. FIGS. 8A to 8C are schematic enlarged cross-sectional views of the substrate W cut along the xz cross section.

A substrate W illustrated in FIG. 8A has a base material S and a laminated structure M. The laminated structure M is a three-dimensional laminated structure in which a plurality of layers including silicon nitride layers are arranged side by side through gaps D. Here, the substrate W is arranged so as to spread in the xy plane. The laminated structure M is located on the upper surface of the base material S. The laminated structure M extends from the upper surface of the base material S along the Z-axis. The gaps D are formed in the laminated structure M. Here, the gaps D reach the base material S, thereby exposing part of the base material S.

The laminated structure M has a plurality of silicon oxide layers Ma and a plurality of silicon nitride layers Ea. The silicon oxide layers Ma and the silicon nitride layers Ea are alternately laminated. The silicon oxide layers Ma and the silicon nitride layers Ea are piled on the upper surface of the base material S.

As illustrated in FIG. 8B, the substrate W is processed with a processing liquid L in the substrate processing apparatus 100. For example, when the silicon nitride layers Ea of the substrate W are etched by phosphatizing, each silicon nitride layer Ea is partially removed.

As illustrated in FIG. 8C, the silicon nitride layers Ea are sufficiently removed from the laminated structure M by further phosphatizing, so that the silicon oxide layers Ma and the silicon nitride layers Ea that have not been etched by the processing liquid L remain in the laminated structure M. As described above, the silicon nitride layers Ea are etched from the substrate W by phosphatizing.

At this time, when bubbles are generated in the processing liquid L so that the bubbles come into contact with the entire surface of the substrate W, the bubbles promote the replacement of the processing liquid L on the surface of the substrate W. Therefore, processing unevenness for each substrate W can be suppressed.

In the substrate processing apparatus 100 illustrated in FIGS. 2 to 7, the bubble generating pipes 136 extend over the entire surface of each substrate W and each supply bubbles to the entire surface of each substrate W, but the embodiment is not limited to this. Each bubble generating pipe 136 may be shorter than the length of the target substrates W along the X-axis. Further, in the substrate processing apparatus 100 illustrated in FIGS. 2 to 7, the flow rate control mechanisms 140a to 140c control the flow rates of the gases supplied to the central bubble generating pipes 136a, and the end bubble generating pipes 136b and 136c, respectively, but the embodiment is not limited to this.

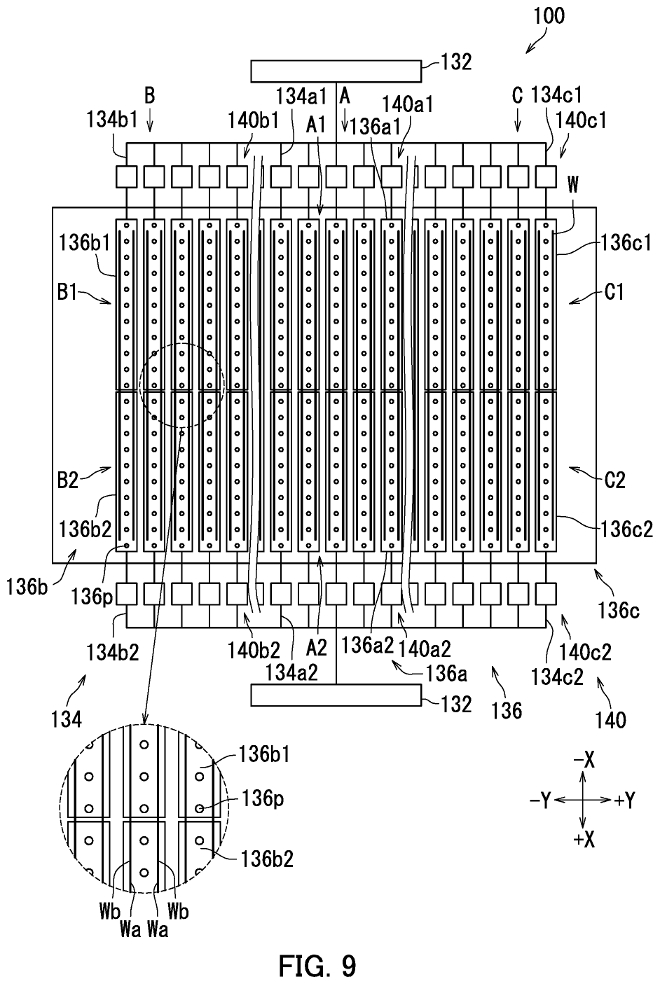

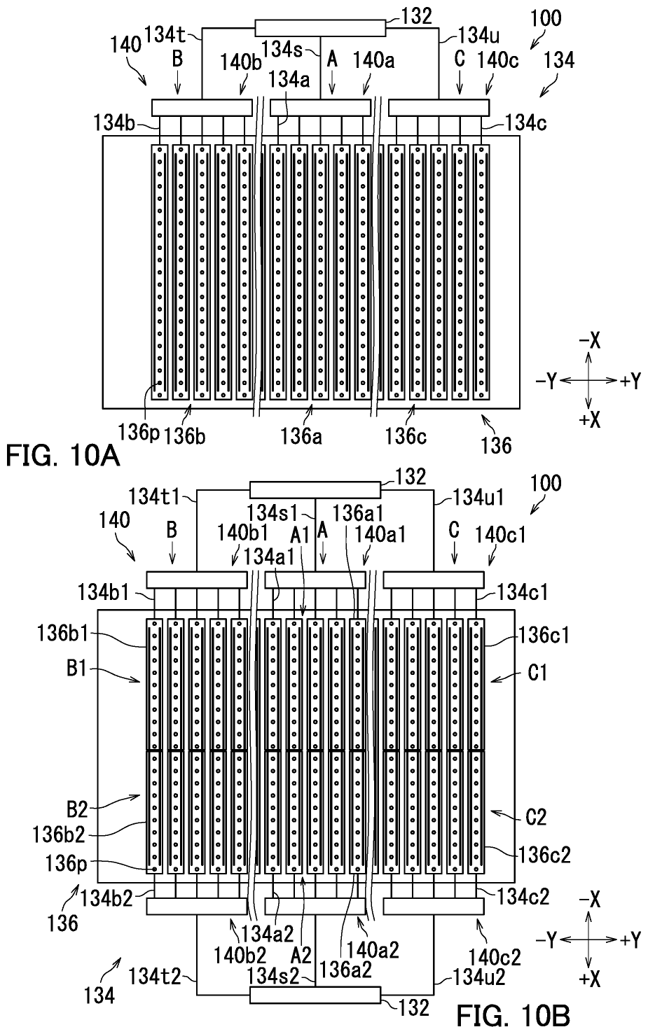

Next, a substrate processing apparatus 100 according to the embodiment will be described with reference to FIGS. 1A to 10B. FIGS. 9, 10A and 10B are schematic top views of their respective substrate processing apparatuses 100 according to the embodiment.

As illustrated in FIG. 9, a plurality of bubble generating pipes 136 are arranged in a processing tank 110. The bubble generating pipes 136 include central bubble generating pipes 136a arranged below substrates W in a central region A, end bubble generating pipes 136b arranged below substrates W in an end region B, and end bubble generating pipes 136c arranged below substrates W in an end region C.

Here, the central region A is divided into a region A1 located on the negative half side of the X-axis, and a region A2 located on the positive half side of the X-axis. Further, the end region B is divided into a region B1 located on the negative half side of the X-axis, and a region B2 located on the positive half side of the X-axis. Similarly, the end region C is divided into a region C1 located on the negative half side of the X-axis, and a region C2 located on the positive half side of the X-axis.

The central bubble generating pipes 136a include central bubble generating pipes 136a1 located in the region A1, and central bubble generating pipes 136a2 located in the region A2. The central bubble generating pipes 136a1 and the central bubble generating pipes 136a2 are aligned in a straight line for each pair. The central bubble generating pipes 136a1 exemplify first central pipes. The central bubble generating pipes 136a2 exemplify second central pipes.

The end bubble generating pipes 136b include end bubble generating pipes 136b1 located in the region B1, and end bubble generating pipes 136b2 located in the region B2. The end bubble generating pipes 136b1 and the end bubble generating pipes 136b2 are aligned in a straight line for each pair. Similarly, the end bubble generating pipes 136c include end bubble generating pipes 136c1 located in the region C1, and end bubble generating pipes 136c2 located in the region C2. The end bubble generating pipes 136c1 and the end bubble generating pipes 136c2 are aligned in a straight line for each pair. The end bubble generating pipes 136b1 and 136c1 exemplify first end pipes. The end bubble generating pipes 136b2 and 136c2 exemplify second end pipes.

Therefore, on the negative half side of the X-axis, the end bubble generating pipes 136b1, the central bubble generating pipes 136a1 and the end bubble generating pipes 136c1 are arranged in this order at equal intervals from the negative half side to the positive half side of the Y-axis. Further, on the positive half side of the X-axis, the end bubble generating pipes 136b2, the central bubble generating pipes 136a2 and the end bubble generating pipes 136c2 are arranged in this order at equal intervals from the negative half side to the positive half side of the Y-axis.

In the present specification, of a plurality of gas supply pipes 134, the gas supply pipes 134 connected to the central bubble generating pipes 136a1 and 136a2 may be referred to as gas supply pipes 134a1 and 134a2, respectively. Similarly, of the plurality of gas supply pipes 134, the gas supply pipes 134 connected to the end bubble generating pipes 136b1 and 136b2 may be referred to as gas supply pipes 134b1 and 134b2, respectively, and the gas supply pipes 134 connected to the end bubble generating pipes 136c1 and 136c2 may be referred to as gas supply pipes 134c1 and 134c2, respectively.

In the substrate processing apparatus 100 illustrated in FIG. 9, the gas supply pipes 134a1, 134b1, and 134c1 connect a gas supply source 132 to the central bubble generating pipes 136a1, the end bubble generating pipes 136b1, and the end bubble generating pipes 136c1, respectively. Further, the gas supply pipes 134a2, 134b2, and 134c2 connect a gas supply source 132 to the central bubble generating pipes 136a2, the end bubble generating pipes 136b2, and the end bubble generating pipes 136c2, respectively. Note that in FIG. 9, two gas supply sources 132 are illustrated on the negative and positive half sides of the X-axis with respect to the processing tank 110, but the number of gas supply sources 132 may be one.

In the present specification, the flow rate control mechanisms 140 that control the flow rates of the gases supplied to the gas supply pipes 134a1 and 134a2 may be referred to as flow rate control mechanisms 140a1 and 140a2. Similarly, in the case of a plurality of flow rate control mechanisms 140, the flow rate control mechanisms 140 that control the flow rates of the gases supplied to the gas supply pipes 134b1 and 134b2 may be referred to as flow rate control mechanisms 140b1 and 140b2, and the flow rate control mechanisms 140 that control the flow rates of the gases supplied to the gas supply pipes 134c1 and 134c2 may be referred to as flow rate control mechanisms 140c1 and 140c2.

The central bubble generating pipes 136a1 are supplied, through the gas supply pipes 134a1, with their respective gases whose flow rates are controlled by the flow rate control mechanisms 140a1. Further, the central bubble generating pipes 136a2 are supplied, through the gas supply pipes 134a2, with their respective gases whose flow rates are controlled by the flow rate control mechanisms 140a2. Similarly, the end bubble generating pipes 136b1 to 136c2 are supplied, through the gas supply pipes 134b1 to 134c2, with their respective gases whose flow rates are controlled by the flow rate control mechanisms 140b1 to 140c2.

Here, two bubble generating pipes are aligned in a straight line along the X-axis. In a plan view, the boundary between the two bubble generating pipes aligned in a straight line is located between two adjacent substrates W. For example, the end bubble generating pipes 136b1 and the end bubble generating pipes 136b2 are aligned in a straight line for each pair.

The substrate processing apparatus 100 according to the embodiment enables the plurality of substrates W aligned along the Y-axis to be supplied with their respective gases at different flow rates, through the central bubble generating pipes 136a1 and 136a2 in the central region A and the end bubble generating pipes 136b1, 136b2, 136c1 and 136c2 in the end regions B and C. Therefore, since bubbles can be generated substantially evenly for each substrate W, processing unevenness for each substrate W can be suppressed.

When the bubble generating pipes 136 are supplied with their respective gases from the gas supply pipes 134a1 to 134c2, the flow rate in the upstream portion of each bubble generating pipe 136 may be larger than the flow rate in the downstream portion thereof. For example, of each central bubble generating pipe 136a1, the flow rate in the upstream portion located on the negative half side of the X-axis is larger than the flow rate in the downstream portion. Of each central bubble generating pipe 136a2, the flow rate in the upstream portion located on the positive half side of the X-axis may be larger than the flow rate in the downstream portion. In this case, in the substrate processing apparatus 100 according to the embodiment, the substrates W arranged along the Y-axis are supplied with their respective gases separately from the bubble generating pipes 136 on the negative half side of the X-axis and the bubble generating pipes 136 on the positive half side of the X-axis. As a result, more gas can be supplied to the outer peripheral region of one substrate W than to the central region thereof. In this case, even when the processing liquid flows in the in-plane direction of the substrate W, bubbles can be evenly generated in the in-plane direction of the substrate W, and as a result, processing unevenness in the in-plane direction of the substrate W can be suppressed.

Note that in the substrate processing apparatus 100 illustrated in FIGS. 1A to 9, the flow rate control mechanisms 140 are provided for the bubble generating pipes 136, but the embodiment is not limited to this. One flow rate control mechanism 140 may control the flow rates of gases supplied to several bubble generating pipes 136.

As illustrated in FIG. 10A, a plurality of bubble generating pipes 136 extending along the X-axis are arranged in a processing tank 110. End bubble generating pipes 136b, central bubble generating pipes 136a, and end bubble generating pipes 136c are arranged in this order at equal intervals from the negative half side to the positive half side of the Y-axis.

Gas supply pipes 134 include common pipes 134s, 134t, and 134u, and gas supply pipes 134a, 134b, and 134c. Here, the plurality of central bubble generating pipes 136a are connected to a common flow rate control mechanism 140a through the plurality of gas supply pipes 134a. The plurality of end bubble generating pipes 136b are connected to a common flow rate control mechanism 140b through the plurality of gas supply pipes 134b. Similarly, the plurality of end bubble generating pipes 136c are connected to a common flow rate control mechanism 140c through the plurality of gas supply pipes 134c.

The common pipe 134s connects a gas supply source 132 and the flow rate control mechanism 140a. The common pipe 134t connects the gas supply source 132 and the flow rate control mechanism 140b. The common pipe 134u connects the gas supply source 132 and the flow rate control mechanism 140c.

The plurality of central bubble generating pipes 136a are supplied, from the gas supply source 132 through the gas supply pipes 134a, with their respective gases whose flow rates are controlled by the common flow rate control mechanism 140a. The plurality of end bubble generating pipes 136b are supplied, from the gas supply source 132 through the gas supply pipes 134b, with their respective gases whose flow rates are controlled by the common flow rate control mechanism 140b. The plurality of end bubble generating pipes 136c are also supplied, from the gas supply source 132 through the gas supply pipes 134c, with their respective gases whose flow rates are controlled by the common flow rate control mechanism 140c.

Therefore, the central bubble generating pipes 136a are supplied with their respective gases whose flow rates are controlled by the flow rate control mechanism 140a. The end bubble generating pipes 136b and 136c are supplied with their respective gases whose flow rates are controlled by the flow rate control mechanisms 140b and 140c. Therefore, the flow rates of the gases supplied to the end bubble generating pipes 136b and 136c located below substrates W in end regions B and C can be larger than the flow rates of the gases supplied to the central bubble generating pipes 136a located below the substrates W in a central region A. This configuration enables the central bubble generating pipes 136a and the end bubble generating pipes 136b and 136c to each generate bubbles at almost an equal amount, thereby suppressing processing unevenness for each substrate W.

In the substrate processing apparatus 100 described above with reference to FIG. 9, the bubble generating pipes 136 are aligned in a straight line two each along the X-axis. In the substrate processing apparatus 100 described above with reference to FIGS. 10A and 10B, the common flow rate control mechanism 140a, the common flow rate control mechanism 140b, and the common flow rate control mechanism 140c are provided for the central region A, the end region B, and the end region C, respectively. However, the embodiment is not limited thereto. Bubble generating pipes 136 may be aligned in a straight line two each along the X-axis, and a common flow rate control mechanism 140 may be provided for each of the regions A1 to C2.

As illustrated in FIG. 10B, gas supply pipes 134 include common pipes 134s1, 134s2, 134t1, 134t2, 134u1, and 134u2, and gas supply pipes 134a1, 134a2, 134b1, 134b2, 134c1, and 134c2. A gas supply source 132 is connected to a flow rate control mechanism 140a1 through the common pipe 134s1. The gas supply source 132 is connected to a flow rate control mechanism 140b1 through the common pipe 134t1, and is connected to a flow rate control mechanism 140c1 through the common pipe 134u1.

Similarly, a gas supply source 132 is connected to a flow rate control mechanism 140a2 through the common pipe 134s2. The gas supply source 132 is connected to a flow rate control mechanism 140b2 through the common pipe 134t2, and is connected to a flow rate control mechanism 140c2 through the common pipe 134u2.

Similar to the above description, central bubble generating pipes 136a1 are supplied, through the gas supply pipes 134a1, with their respective gases whose flow rates are controlled by the flow rate control mechanism 140a1. Further, central bubble generating pipes 136a2 are supplied, through the gas supply pipes 134a2, with their respective gases whose flow rates are controlled by the flow rate control mechanism 140a2. Similarly, end bubble generating pipes 136b1 to 136c2 are supplied, through the gas supply pipes 134b1 to 134c2, with their respective gases whose flow rates are controlled by the flow rate control mechanisms 140b1 to 140c2, respectively.

Note that in the above description with reference to FIGS. 1A to 10B, each substrate W is supplied with a gas from a lower side of the processing liquid L stored in the processing tank 110, but the embodiment is not limited to this. The substrates W may be supplied, from the lower side of the processing liquid L stored in the processing tank 110, with not only the gases but also a liquid.

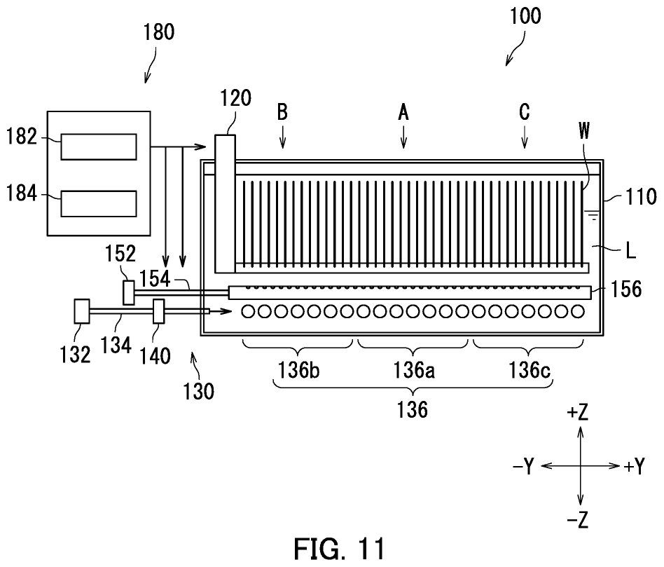

Next, a substrate processing apparatus 100 according to the embodiment will be described with reference to FIGS. 1A to 11. FIG. 11 is a schematic view of the substrate processing apparatus 100 according to the embodiment. The substrate processing apparatus 100 illustrated in FIG. 11 has the same configuration as the substrate processing apparatus 100 described above with reference to FIG. 2, except that a liquid supply section 150 is further provided. Duplicate description is omitted for the purpose of avoiding redundancy.

As illustrated in FIG. 11, the substrate processing apparatus 100 further includes the liquid supply section 150. The liquid supply section 150 supplies a liquid to a processing tank 110. The liquid supply section 150 supplies a liquid in a processing tank 110. Typically, the liquid supply section 150 supplies a processing liquid L in the processing tank 110. In this case, it is preferable that the liquid to flow upward from the lower position in the processing tank 110 be supplied from the liquid supply section 150 to the processing liquid L. As an example, the liquid may be the same type of processing liquid L as the processing liquid L stored in the processing tank 110.

When the liquid supply section 150 supplies a processing liquid L, the processing liquid to flow upward moves upward along the surfaces of substrates W in the processing liquid while pushing contact part with the substrates W. A fresh processing liquid L existing in the surroundings enters the place after the processing liquid flowing upward has passed. In this way, the processing liquid flowing upward comes into contact with the surfaces of the substrates W, so that agitation becomes possible at the surface side of each substrate W. Accordingly, the processing liquid L on the surface of each substrate W can be replaced with the fresh processing liquid. As a result, the processing speed of the substrates W can be improved.

The liquid supply section 150 includes a liquid supply source 152, liquid supply pipes 154, and liquid discharge pipes 156. The liquid is supplied from the liquid supply source 152. The liquid supply source 152 is located outside the processing tank 110. Note that the liquid supply source 152 may be used so as to circulate the liquid once used as the processing liquid L in the processing tank 110. The liquid discharge pipes 156 extend along the Y-axis. Here, the liquid discharge pipes 156 extend in the direction orthogonal to bubble generating pipes 136.

The liquid supply pipes 154 connect the liquid supply source 152 and the liquid discharge pipes 156. The liquid supplied from the liquid supply source 152 flows through the liquid supply pipes 154 to the liquid discharge pipes 156. At least part of each liquid supply pipe 154 is arranged outside the processing tank 110.

The liquid discharge pipes 156 are arranged in the processing tank 110. Typically, the liquid discharge pipes 156 are arranged at the bottom side of the processing tank 110. The liquid discharge pipes 156 may be arranged vertically above the bubble generating pipes 136. Alternatively, the liquid discharge pipes 156 may be arranged vertically below the bubble generating pipes 136. The liquid discharge pipes 156 extend along the X-axis. Therefore, in a plan view, the liquid discharge pipes 156 are orthogonal to the bubble generating pipes 136.

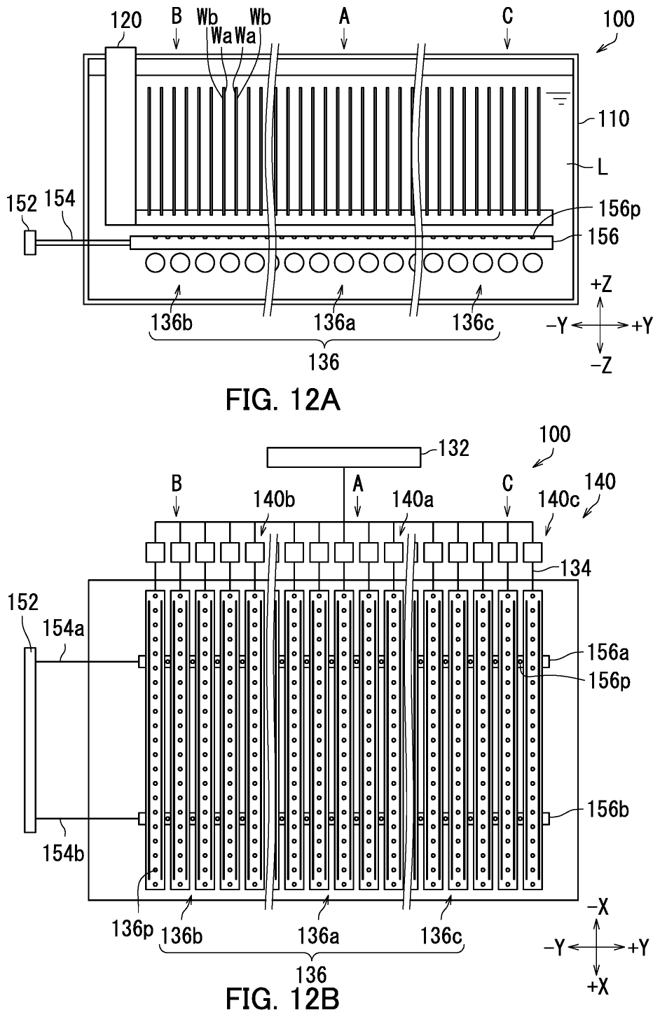

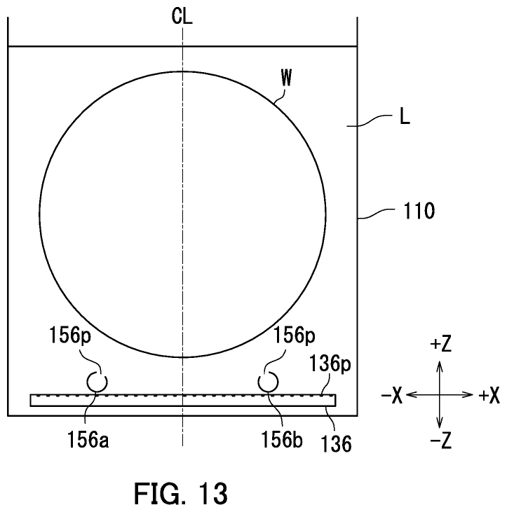

Next, a substrate processing apparatus 100 according to the embodiment will be described with reference to FIGS. 1A to 13. FIG. 12A is a schematic side view of the substrate processing apparatus 100 according to the embodiment. FIG. 12B is a schematic top view of the substrate processing apparatus 100. FIG. 13 is a schematic view of the substrate processing apparatus 100. The substrate processing apparatus 100 illustrated in FIGS. 12A and 12B has the same configuration as the substrate processing apparatus 100 described above with reference to FIGS. 3A and 4 except that a liquid supply section 150 is further provided. Duplicate description is omitted for the purpose of avoiding redundancy. FIG. 13 illustrates a virtual center line CL extending in the vertical direction through the center of substrates W.

As illustrated in FIGS. 12A and 12B, liquid discharge pipes 156 include a liquid discharge pipe 156a and a liquid discharge pipe 156b. The liquid discharge pipes 156a and 156b extend parallel to each other. The liquid discharge pipes 156a and 156b extend extends along Y-axis. The liquid discharge pipe 156a and the liquid discharge pipe 156b are arranged in order from the negative half side to the positive half side of the X-axis.

Each of the liquid discharge pipes 156a and 156b is provided with a plurality of openings 156p. The plurality of openings 156p in each liquid discharge pipe 156 are aligned in a row. Intervals at which the plurality of openings 156 are aligned is substantially equal to intervals at which the substrates W are aligned. Each of the plurality of openings 156p is located between corresponding adjacent substrates W in the alignment direction. The liquid discharge pipes 156a and 156b have the same configuration. Note that in this specification, the liquid discharge pipes 156a and 156b may be collectively referred to as the liquid discharge pipes 156.

The liquid discharge pipe 156a is supplied with a liquid from a liquid supply source 152 through a liquid supply pipe 154a. The liquid discharge pipe 156b is also supplied with a liquid from the liquid supply source 152 through a liquid supply pipe 154b.

Each of the liquid discharge pipes 156 discharges a processing liquid L to a processing tank 110 from the plurality of openings 156p. In this case, it is preferable that the plurality of openings 156p face upward from the lower position with respect to the processing liquid L in the processing tank 110. Here, the plurality of openings 156p are equal in size and intervals.

As illustrated in FIG. 13, bubble generating pipes 136 and the liquid discharge pipes 156a and 156b are arranged in the processing tank 110. Openings 136p of each bubble generating pipe 136 are provided in the upper part of the bubble generating pipe 136 so that the discharge direction thereof is along the vertical direction.

On the other hand, the openings 156p of each of the liquid discharge pipes 156a and 156b are provided at a position inclined with respect to the vertical direction (Z-axis) so that their respective discharge directions face the center of the substrates W. Therefore, when diagonally upward liquids discharged from the openings 156p of the liquid discharge pipe 156a merge with diagonally upward liquid flows discharged from the openings 156p of the liquid discharge pipe 156b, a very strong upflow flowing upward inside the processing tank 110 can be formed.

In the substrate processing apparatus 100 according to the embodiment, the flow rate of a gas supplied to each of end bubble generating pipes 136b and end bubble generating pipes 136c located in end regions B and C is made larger than the flow rate of a gas supplied to each of central bubble generating pipes 136a located in a central region A. This configuration enables the central bubble generating pipes 136a and the end bubble generating pipes 136b and 136c to each generate bubbles at almost an equal amount. When the upflow is formed in particular, the speed of substrate processing increases with the flow of bubbles. Even when the substrate processing is performed at such a high speed, processing unevenness can be suppressed over the surfaces of each substrate W.

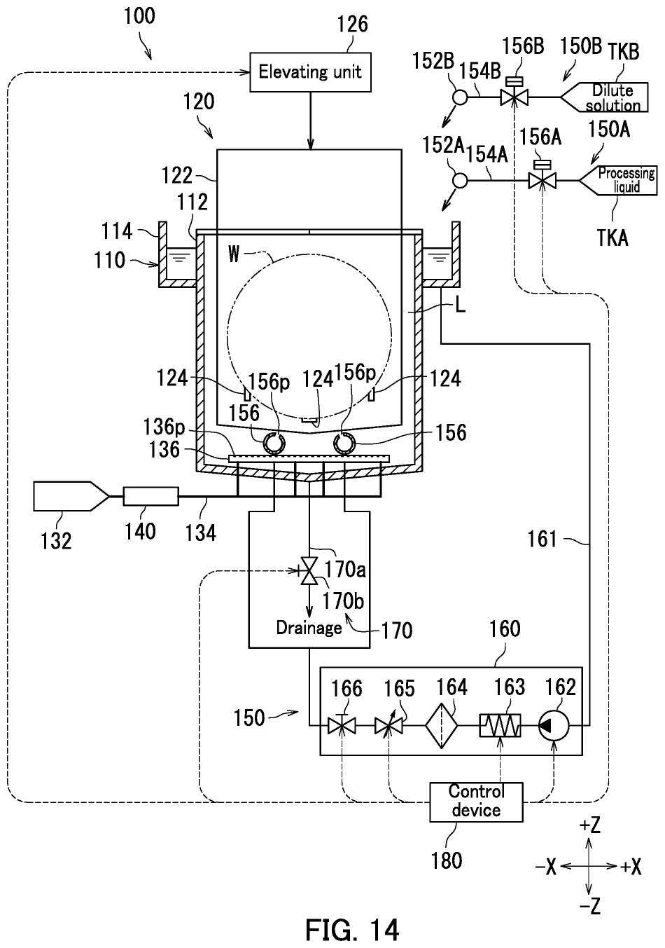

Next, a substrate processing apparatus 100 according to the embodiment will be described with reference to FIGS. 1A to 14. FIG. 14 is a schematic view of the substrate processing apparatus 100 according to the embodiment.

As illustrated in FIG. 14, a processing tank 110 has a double tank structure including an inner tank 112 and an outer tank 114. The inner tank 112 and the outer tank 114 each have an upper opening that opens upward. The inner tank 112 is configured to store a processing liquid L and to accommodate a plurality of substrates W. The outer tank 114 is provided on the outer peripheral surface of an upper opening of the inner tank 112.

The substrate processing apparatus 100 further includes a flow rate adjusting mechanism 160. The flow rate adjusting mechanism 160 is used for circulation of the processing liquid L. In substrate processing, the flow rate adjusting mechanism 160 circulates the processing liquid L stored in the processing tank 110 and supplies the processing liquid L to each of liquid discharge pipes 156.

The flow rate adjusting mechanism 160 includes a pipe 161, a pump 162, a heater 163, a filter 164, an adjusting valve 165 and a valve 166. The pump 162, the heater 163, the filter 164, the adjusting valve 165 and the valve 166 are arranged in this order from the upstream to the downstream of the pipe 161.

The pipe 161 guides the processing liquid L discharged from the processing tank 110 to the processing tank 110 again. The plurality of liquid discharge pipes 156 are connected to the downstream end of the pipe 161.

The pump 162 sends the processing liquid L from the pipe 161 to the plurality of liquid discharge pipes 156. Therefore, the liquid discharge pipes 156 supply, to the processing tank 110, the processing liquid L supplied from the pipe 161. The heater 163 heats the processing liquid L flowing through the pipe 161. The temperature of the processing liquid L is adjusted by the heater 163. The filter 164 filters the processing liquid L flowing through the pipe 161.

The adjusting valve 165 adjusts the opening degree of the pipe 161 to adjust the flow rate of the processing liquid L supplied to the plurality of liquid discharge pipes 156. Specifically, the adjusting valve 165 includes a valve body (not illustrated) having a valve seat inside, a valve element that opens and closes the valve seat, and an actuator (not illustrated) that moves the valve element between an open position and a closed position. The valve 166 opens and closes the pipe 161.

The plurality of liquid discharge pipes 156 supply the processing liquid L to the inner tank 112 of the processing tank 110. The plurality of liquid discharge pipes 156 are arranged at the bottom side of the inner tank 112 inside the inner tank 112 of the processing tank 110. Each of the plurality of liquid discharge pipes 156 has a substantially tubular shape.

Specifically, each of the plurality of liquid discharge pipes 156 has a plurality of openings 156p. FIG. 14 illustrates one opening 156p for one liquid discharge pipe 156. Each of the plurality of liquid discharge pipes 156 supplies the processing liquid L to the inner tank 112 from the plurality of openings 156p.

The substrate processing apparatus 100 further includes a processing liquid supply section 150A and a diluent supply section 150B. The processing liquid supply section 150A supplies the processing liquid L to the processing tank 110. For example, a solution in which approximately 85% by mass of phosphoric acid (H₃PO₄) and approximately 15% by mass of water (deionized water) are mixed can be employed as the processing liquid L.

The processing liquid supply section 150A includes a nozzle 152A, a pipe 154A, and a valve 156A. The nozzle 152A discharges the processing liquid L to the inner tank 112. The nozzle 152A is connected to the pipe 154A. The pipe 154A is supplied with the processing liquid L from a processing liquid supply source TKA. The valve 156A is arranged in the pipe 154A. When the valve 156A is opened, the processing liquid L discharged from the nozzle 152A is supplied into the inner tank 112.

The diluent supply section 150B supplies a dilute solution to the processing tank 110. The diluent supply section 150B includes a nozzle 152B, a pipe 154B, and a valve 156B. The nozzle 152B discharges the dilute solution to the outer tank 114. The nozzle 152B is connected to the pipe 154B. Any of DIW (deionized water), carbonated water, electrolytic ionized water, hydrogen water, ozone water and hydrochloric acid water having a dilution concentration (for example, about 10 ppm to 100 ppm) may be adopted as the dilute solution supplied to the pipe 154B. The pipe 154B is supplied with the dilute solution from a dilute solution supply source TKB. The valve 156B is arranged in the pipe 154B. When the valve 156B is opened, the dilute solution discharged from the nozzle 152B is supplied into the outer tank 114.

The substrate processing apparatus 100 further includes a drainage section 170. The drainage section 170 drains the processing liquid L in the processing tank 110.

The drainage section 170 includes a drainage pipe 170a and a valve 170b. The drainage pipe 170a is connected to the bottom wall of the inner tank 112 of the processing tank 110. The valve 170b is arranged in the drainage pipe 170a. When the valve 170b is opened, the processing liquid L stored in the inner tank 112 is drained to the outside through the drainage pipe 170a. The processing liquid L to be drained is sent to a waste liquid treatment device (not illustrated) for treatment.

The embodiment of the present disclosure has been described above with reference to the drawings. However, the present disclosure is not limited to the above-described embodiment, and may be implemented in various aspects without departing from the gist thereof. In addition, various aspects may be created by appropriately combining the plurality of components disclosed in the above-described embodiment. For example, some components may be removed from all the components described in the embodiment. Further, components across different configurations may be combined as appropriate. The drawings schematically illustrate each component as a main body in order to make it easier to understand. The thickness, length, number, intervals and the like of illustrated components may differ from the actual ones for the convenience of the drawing. Further, the material, shape, dimensions or the like of each component illustrated in the above embodiment are examples and not particularly limited, and various modifications may be made without substantially deviating from the effects of the present disclosure.

For example, in the above description with reference to FIGS. 1A to 14, each bubble generating pipe 136 extends in a direction orthogonal to the normal direction (Y-axis) of the main surfaces of substrates W, but the embodiment is not limited to this. However, it is preferable that different bubble generating pipes 136 be arranged below each of the central region and the end regions of the substrate row that is the plurality of substrates W.

What is claimed is:

1. A substrate processing apparatus comprising:
a substrate holding section that holds a plurality of substrates, which form a substrate row, aligned in a row in a row direction;
a processing tank that stores a processing liquid allowing the substrates held by the substrate holding section to be immersed in; and
a plurality of bubble generating pipes that each supply a gas to the processing liquid to generate bubbles in the processing liquid, wherein
a flow rate of a gas supplied to an end bubble generating pipe, located below an end of the substrate row immersed in the processing liquid, of the plurality of bubble generating pipes differs from a flow rate of a gas supplied to a central bubble generating pipe, located below a center of the substrate row, of the plurality of bubble generating pipes.

2. The substrate processing apparatus according to claim 1, wherein the plurality of bubble generating pipes extend in a direction orthogonal to a normal direction of each main surface of the substrates.

3. The substrate processing apparatus according to claim 1, wherein the central bubble generating pipe is smaller in number per unit area than the end bubble generating pipe.

4. The substrate processing apparatus according to claim 1, wherein the flow rate of the gas supplied to the end bubble generating pipe, located below the end of the substrate row immersed in the processing liquid, of the plurality of bubble generating pipes is larger than the flow rate of the gas supplied to the central bubble generating pipe located below the center of the substrate row.

5. The substrate processing apparatus according to claim 4 further comprising:
a plurality of gas supply pipes connected to the plurality of bubble generating pipes; and
a flow rate control mechanism that controls a flow rate of a gas flowing through each of the plurality of gas supply pipes, wherein
the flow rate control mechanism controls the flow rate of the gas flowing through each of the plurality of gas supply pipes so that the flow rate of the gas supplied to the end bubble generating pipe is larger than the flow rate of the gas supplied to the central bubble generating pipe.

6. The substrate processing apparatus according to claim 5 further comprising a pressure gauge that measures a pressure of a gas flowing through a gas supply pipe connected to the end bubble generating pipe, and a pressure of a gas flowing through a gas supply pipe connected to the central bubble generating pipe.

7. The substrate processing apparatus according to claim 6 further comprising a controller that controls the flow rate control mechanism, wherein
the controller controls the flow rate of the gas flowing through each of the plurality of gas supply pipes based on the pressure of the gas flowing through the gas supply pipe connected to the end bubble generating pipe, and the pressure of the gas flowing through the gas supply pipe connected to the central bubble generating pipe.

8. The substrate processing apparatus according to claim 6 further comprising:
a controller that controls the flow rate control mechanism; and
storage that stores a control program, wherein
the controller controls the flow rate control mechanism according to the control program.

9. The substrate processing apparatus according to claim 1, wherein
the central bubble generating pipe includes:
a first central pipe located below a first side in a horizontal direction with respect to the substrates;
a second central pipe separated from the first central pipe, the second central pipe being aligned in a straight line along with the first central pipe, the second central pipe being located below a second side in the horizontal direction with respect to the substrates, and
the end bubble generating pipe includes:
a first end pipe located below the first side in the horizontal direction with respect to the substrates; and
a second end pipe separated from the first end pipe, the second end pipe being aligned in a straight line along with the first end pipe, the second end pipe being located below the second side in the horizontal direction with respect to the substrates.

10. The substrate processing apparatus according to claim 1 further comprising a liquid discharge pipe located in the processing tank.

11. The substrate processing apparatus according to claim 10, wherein the liquid discharge pipe is located so as to extend parallel to the normal direction of each main surface of the substrates.

12. The substrate processing apparatus according to claim 1, wherein the processing liquid contains a phosphoric acid liquid.

13. A substrate processing method comprising:
immersing a plurality of substrates in a processing liquid stored in a processing tank, the plurality of substrates being aligned in a row in a row direction and forming a substrate row; and
supplying a gas to each of a plurality of bubble generating pipes arranged in the processing tank to generate bubbles in the processing liquid so that the substrates immersed in the processing liquid are each supplied with the bubbles, wherein
the supplying the gas includes making a difference between a flow rate of a gas supplied to an end bubble generating pipe, located below an end of the substrate row, of the plurality of bubble generating pipes and a flow rate of a gas supplied to a central bubble generating pipe, located below a center of the substrate row, of the plurality of bubble generating pipes.

14. The substrate processing method according to claim 13, wherein the plurality of bubble generating pipes extend in a direction orthogonal to a normal direction of each main surface of the substrates.

15. The substrate processing method according to claim 13, wherein in the making the difference, the flow rate of the gas supplied to the end bubble generating pipe, located below the end of the substrate row, of the plurality of bubble generating pipes is larger than the flow rate of the gas supplied to the central bubble generating pipe located below the center of the substrate row.

16. The substrate processing method according to claim 13, wherein
the supplying the gas further includes:
supplying a gas at an equal flow rate to each of the end bubble generating pipe and the central bubble generating pipe; and
measuring, in the supplying the gas at the equal flow rate, a pressure of a gas flowing through a gas supply pipe connected to the end bubble generating pipe, and a pressure of a gas flowing through a gas supply pipe connected to the central bubble generating pipe, and
the making the difference includes setting, based on a result of the measuring, a flow rate of the gas flowing through the gas supply pipe connected to the end bubble generating pipe, and a flow rate of the gas flowing through the gas supply pipe connected to the central bubble generating pipe.
